(19) United States
(12) Patent Application Publication
(10) Pub. No.: US 2012/0153985 A1
(43) Pub. Date: Jun. 21, 2012

(54) TESTING APPARATUS FOR TESTING PORTS OF PRINTED CIRCUIT BOARD

(75) Inventors: BO ZHANG, Shenzhen City (CN); YANG-XIN CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/170,969

(22) Filed: Jun. 28, 2011

(30) Foreign Application Priority Data
Dec. 15, 2010 (CN) 201010589944.9

(51) Int. Cl. G01R 31/304

(52) U.S. Cl. 324/763.01

(57) ABSTRACT

A test assembly includes a printed circuit board, a first subsidiary test chipset, a second subsidiary test chipset, and a main test chipset. The printed circuit board includes a first CPU socket and a second CPU socket. The first CPU socket includes a first socket pin. The second CPU socket includes a second socket pin. The first subsidiary test chipset connects to the first CPU socket. The second subsidiary test chipset connects to the second CPU socket. The main test chipset connects to the first subsidiary test chipset and the second subsidiary test chipset. The first subsidiary test chipset outputs a first signal to the first socket pin. The second subsidiary test chipset receives a second signal from the second socket pin. The main test chipset compares the first signal and the second signal to test a connection of the first socket pin and the second socket pin.

### BACKGROUND

1. Technical Field

The present disclosure relates to testing apparatuses, and more particularly to a testing apparatus for testing ports of a printed circuit board.

2. Description of Related Art

After assembling of a printed circuit board into an electronic device, an overall test is required to check the functions of the printed circuit board. The test mainly aims at the defects such as open circuit, short circuit as well as the incorrect connection between the chips. After these detections, the error signals from the testing device are analyzed to find out where the error points are on the printed circuit board.

In a conventional arrangement, an untested printed circuit board is connected to a testing board with a plurality of terminals manually. Because the printed circuit board often has a plurality of ports, such as memory slots, and central processing units (CPU) sockets. The CPU sockets often have hundreds of pin holes. It is difficult to test the electrical connection of the hundreds of pin holes especially for some server printed circuit boards, which often have more than one CPU socket mounted thereon.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view an embodiment of a testing apparatus for testing ports of a printed circuit board.

FIG. 2 is a block view of the test apparatus of FIG. 1 test a first port of the printed circuit board.

FIG. 3 is a block view of the test apparatus of FIG. 1 test a second port of the printed circuit board.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

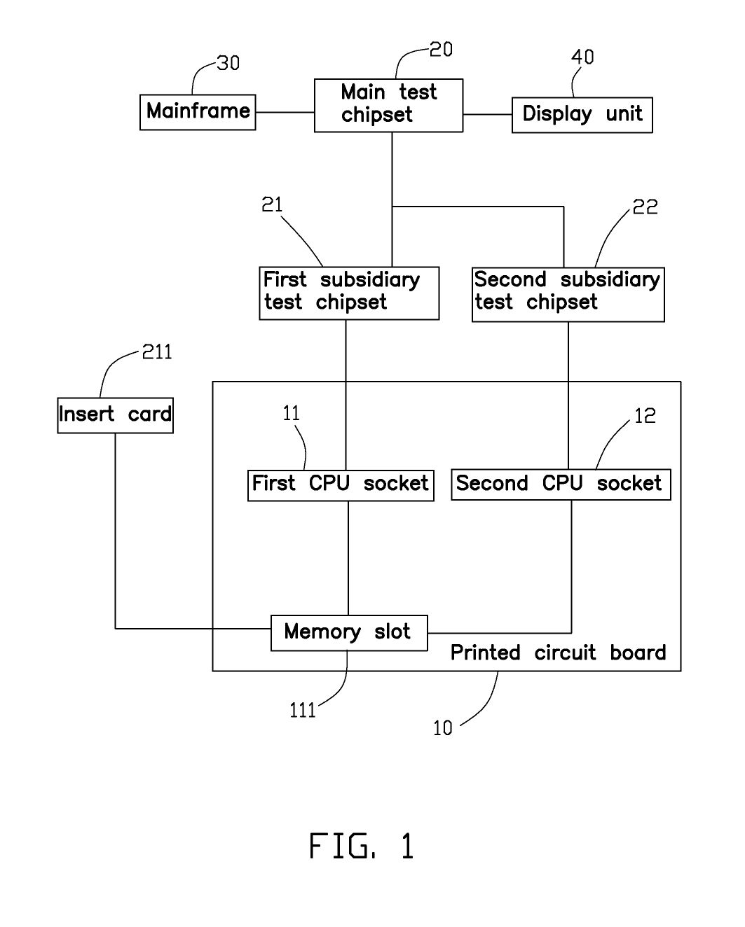

Referring to FIG. 1, a test apparatus in accordance with an embodiment includes a main test chipset 20, a first subsidiary test chipset 21, a second subsidiary test chipset 22, an insert card 211, a mainframe 30, and a display unit 40. The test apparatus is used to test a printed circuit board 10. In one embodiment, the printed circuit board 10 is a server printed circuit board, which has a first CPU socket 11 and a second CPU socket 12. Each of the first CPU socket 11 and the second CPU socket 12 is adapted to receive a CPU mounted thereon. The first CPU socket 11 and the second CPU socket 12 are the same type sockets, and have the same socket pins. The first CPU socket 11 is connected to the memory slot 111. The second CPU socket 12 is also connected to the memory slot 111.

The main test chipset 20 is connected to the mainframe 30 and further connected to the display unit 40. The mainframe 30 is used to store test data. The display unit 40 is used to display test results. The first subsidiary test chipset 21 and the second subsidiary test chipset 22 are connected to the main test chipset 20. The first subsidiary test chipset 21 is connected to the first CPU socket 11. The second subsidiary test chipset 22 is connected to the second CPU socket 12. The insert card 211 is inserted in the memory slot 111 and communicates with the memory slot 111.

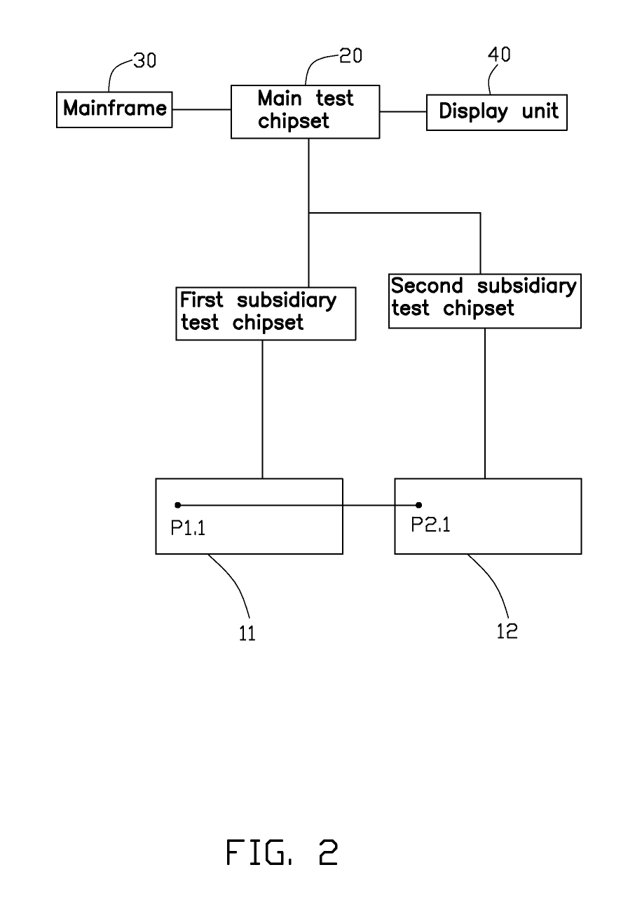

Referring to FIG. 2, the first CPU socket 11 includes a first socket pin P1.1. The second CPU socket 12 includes a second socket pin P2.1. On the printed circuit board 10, the first socket pin P1.1 should have a good connection to the second socket pin P2.1. For testing a connection between the first socket pin P1.1 and the second socket pin P2.1, the main test chipset 20 controls the first subsidiary test chipset 21 to output a first signal to the first socket pin P1.1. Then, the main test chipset 20 controls the second subsidiary test chipset 22 to receive a second signal from the second socket pin P2.1 At last, the main test chipset 20 compares the second signal with the first signal. If the first signal and the second signal are the same, the connection between the first socket pin P1.1 and the second socket pin P2.1 are good. If the first signal and the second signal are not the same, the connection between the first socket pin P1.1 and the second socket pin P2.1 are bad. Therefore, the connection between the first socket pin P1.1 and the second socket pin P2.1 are tested. Using the same method, connections between other pins of the first CPU socket 21 and second CPU socket 22 can be tested. The main test chipset 20 outputs test results to the mainframe 30, which stores the test results. The main test chipset 20 outputs test results to the display unit 40, which displays the test results.

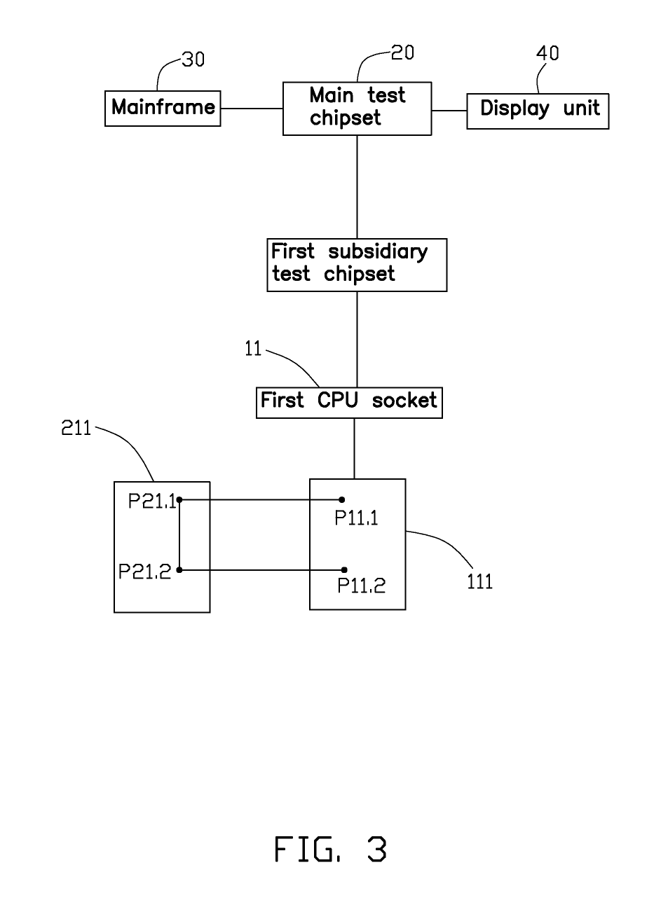

Referring to FIG. 3, the memory slot 111 includes a first memory pin P11.1 and a second memory pin P11.2. The insert card 211 includes a first card pin P21.1 and a second card pin P21.2. The first card pin P21.1 is connected to the second card pin P21.2. When the insert card 211 is inserted in the memory slot 111, the first memory pin P11.1 is connected to the first card pin P21.1, and the second memory pin P11.2 is connected to the second card pin P21.2. For testing a connection between the first CPU 11 and the memory slot 111, the main test chipset 20 controls the first subsidiary test chipset 21 to send a third signal to the first memory pin P11.1 via the first CPU socket 11. Then, the main test chipset 20 controls the second subsidiary test chipset 22 to receive a fourth signal from the second memory pin P11.2. At last, the main test chipset 20 compares the fourth signal with the third signal. If the third signal and the fourth signal are the same, the connection between the first memory pin P11.1 and the first CPU socket 11 are good, and the connection between the second memory pin P21.1 and the first CPU socket 11 are good. If the third signal and the fourth signal are not the same, the connection between the first memory pin P11.1 and the first CPU socket 11 is bad, and/or the connection between the second memory pin P21.1 and the first CPU socket 11 is bad. Using the same method, connections between other pins of the memory slot 111 and the first CPU socket 21 can be tested. A connection between the memory slot 111 and the second CPU socket 22 also can be tested.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A test assembly, comprising:
a printed circuit board comprising a first CPU socket and a second CPU socket, the first CPU socket comprising a first socket pin, the second CPU socket comprising a second socket pin;
a first subsidiary test chipset connected to the first CPU socket;
a second subsidiary test chipset connected to the second CPU socket; and
a main test chipset connected to the first subsidiary test chipset and the second subsidiary test chipset; wherein the first subsidiary test chipset is adapted to output a first signal to the first socket pin, the second subsidiary test chipset is adapted to receive a second signal from the second socket pin, the main test chipset is adapted to compare the first signal and the second signal to test a connection of the first socket pin and the second socket pin.

2. The test assembly of claim 1, wherein a display unit is connected to the main test chipset, and the display unit is adapted to display a compare result of the first signal and the second signal.

3. The test assembly of claim 1, wherein a mainframe is connected to the main test chipset, and the mainframe is adapted to store a compare result of the first signal and the second signal.

4. The test assembly of claim 1, further comprises an insert card, wherein the printed circuit board comprises a memory slot, the insert card is inserted in the memory slot, the memory slot comprises a first memory pin and a second memory pin, the insert card couples the first memory pin to the second memory pin, and the main test chipset is adapted to send a third signal to the first memory pin via the first CPU socket, the main test chipset is adapted to receive a fourth signal from the second memory pin via the first CPU socket, and the main test chipset is adapted to compare the third signal and the fourth signal to test a connection of the first CPU socket and the memory slot.

5. The test assembly of claim 4, wherein the insert card comprises a first card pin and a second card pin connected to the first card pin, the first card pin is connected to the first memory pin, and the second card pin is connected to the second memory pin.

6. The test assembly of claim 1, further comprises an insert card, wherein the printed circuit board comprises a memory slot, the insert card is inserted in the memory slot, the memory slot comprises a first memory pin and a second memory pin, the insert card couples the first memory pin to the second memory pin, and the main test chipset is adapted to send a third signal to the first memory pin via the second CPU socket, the main test chipset is adapted to receive a fourth signal from the second memory pin via the second CPU socket, and the main test chipset is adapted to compare the third signal and the fourth signal to test a connection of the second CPU socket and the memory slot.

7. A test assembly, comprising:
a printed circuit board comprising a first CPU socket and a memory slot, the memory slot comprising a first memory pin and a second memory pin;
an insert card inserted in the memory slot and coupling the first memory pin to the second memory pin;
a main test chipset connected to the first CPU socket; wherein the main test chipset is adapted to send a third signal to the first memory pin via the first CPU socket, the main test chipset is adapted to receive a fourth signal from the second memory pin via the first CPU socket, and the main test chipset is adapted to compare the third signal and the fourth signal to test a connection of the first CPU socket and the memory slot.

8. The test assembly of claim 7, wherein the insert card comprises a first card pin and a second card pin connected to the first card pin, the first card pin is connected to the first memory pin, and the second card pin is connected to the second memory pin.

9. The test assembly of claim 7, wherein the first CPU socket comprises a first socket pin, the printed circuit board further comprise a second CPU socket which comprises a second socket pin; a first subsidiary test chipset is connected to the first CPU socket, a second subsidiary test chipset is connected to the second CPU socket, the main test chipset is connected to the first subsidiary test chipset and the second subsidiary test chipset; the first subsidiary test chipset is adapted to output a first signal to the first socket pin, the second subsidiary test chipset is adapted to receive a second signal from the second socket pin, the main test chipset is adapted to compare the first signal and the second signal to test a connection of the first socket pin and the second socket pin.

10. The test assembly of claim 9, wherein a display unit is connected to the main test chipset, and the display unit is adapted to display a compare result of the first signal and the second signal.

11. The test assembly of claim 9, wherein a mainframe is connected to the main test chipset, and the mainframe is adapted to store a compare result of the first signal and the second signal.
